(19) United States
(12) Patent Application Publication
(10) Pub. No.: US 2008/0237733 A1
(43) Pub. Date: Oct. 2, 2008

(54) STRUCTURE AND METHOD TO ENHANCE CHANNEL STRESS BY USING OPTIMIZED STI STRESS AND NITRIDE CAPPING LAYER STRESS

(75) Inventors: Xiangdong Chen, Poughquag, NY (US); Zhijiong Luo, Carmel, NY (US); Huilong Zhu, Poughkeepsie, NY (US)

Correspondence Address: FREDERICK W. GIBB, III;Gibb & Rahman, LLC, 2568-A RIVA ROAD, SUITE 304, ANNAPOLIS, MD, 21401, US

(73) Assignee: INTERNATIONAL BUSINESS MACHINES CORPORATION, Armonk, NY (US)

(21) Appl. No.: 11/691,699

(22) Filed: Mar. 27, 2007

(51) Int. Cl. H01L 29/78; H01L 21/8232

(52) U.S. Cl. 257/374; 438/221; 257/E21.632; 257/E29.255

(57) ABSTRACT

The embodiments of the invention provide a structure and method to enhance channel stress by using optimized STI stress and nitride capping layer stress. More specifically, a transistor structure is provided comprising a substrate having a first transistor region and a second transistor region, different than the first transistor region. Moreover, first transistors are provided over the first transistor region and second transistors, different than the first transistors, are provided over the second transistors region. The first transistor comprises an NFET and the second transistor comprises a PFET. The structure further includes STI regions in the substrate adjacent sides of the first transistors and the second transistors, wherein the STI regions comprise stress producing regions. Recesses are within at least two of the STI regions, such that portions of at least one of said first stress liner and said second stress liner are positioned within said recesses.

### BACKGROUND

1. Field of the Invention

The embodiments of the invention provide a structure and method to enhance channel stress by using optimized shallow trench isolation (STI) stress and nitride capping layer stress.

2. Description of the Related Art

Stress from STI regions and stress form nitride capping layers can greatly influence metal-oxide-semiconductor field effect transistors (MOSFETs). More specifically, tensile stress in longitudinal direction MOSFET channel regions can enhance n-type field effect transistor (NFET) performance but degrade p-type field effect transistor (PFET) performance. Moreover, compressive stress in the longitudinal direction of channel can enhance PFET performance but degrade NFET performance.

One way to solve this problem is to use dual-stress materials, like dual nitride capping layers, tensile capping layer for NFET and compressive capping layer for PFET; and/or dual STI (shallow trench isolation) stressors. But dual-STI stress is complicated and expensive, and highly impractical, since in many cases, NFET and PFET share one STI. Therefore, what is needed is a simple recess method to recess STI partially and to combine with dual CA capping layer to achieve similar effect of dual-STI and dual nitride capping layers.

### SUMMARY

The embodiments of the invention provide a structure and method to enhance channel stress by using optimized shallow trench isolation (STI) stress and nitride capping layer stress. More specifically, a transistor structure is provided comprising a substrate having a first transistor region and a second transistor region, different than the first transistor region. Moreover, first transistors are provided over the first transistor region and second transistors, different than the first transistors, are provided over the second transistors region. The first transistor comprises an NFET and the second transistor comprises a PFET.

The structure further includes STI regions in the substrate adjacent sides of the first transistors and the second transistors, wherein the STI regions comprise stress producing regions. Recesses are within at least two of the STI regions, such that tops of the STI regions that are recessed are below a top of the substrate.

Additionally, a first stress liner is over the first transistors and a second stress liner, different than the first stress liner, is over the second transistors. Portions of the first stress liner and/or the second stress liner are positioned within the recesses. If all of the STI regions are recessed, then a portion of the first stress liner contacts a portion of the second stress liner within the recesses. If all of the STI regions that are adjacent the first transistors are recessed and none of the STI regions that are adjacent the second transistors are recessed, then portions of the first stress liner are positioned within the recesses and portions of the second stress liner are not positioned within the recesses. The recesses can have a depth larger than a height of the first stress liner and the second stress liner, such that portions of the first stress liner and the second stress liner that are within the recesses can be below a top of the substrate.

Furthermore, all of the STI regions could be recessed. Alternatively, all of the STI regions that are adjacent the first transistor could be recessed; wherein none of the STI regions that are adjacent the second transistors are recessed. In addition, all of the STI regions that are between the first transistors and the second transistors could be recessed.

The embodiments of the invention also provide a method of forming a transistor structure, wherein the method begins by forming first transistors over a first transistor region of a substrate and forming second transistors over a second transistor region of the substrate. The first transistors comprise NFETs and the second transistors comprise PFETs. Next, STI regions are formed in the substrate adjacent sides of the first transistors and the second transistors such that the STI regions comprise stress producing regions. The STI regions are then recessed, such that all of the STI regions can be recessed. Alternatively, all of the STI regions that are adjacent the first transistors can be recessed; wherein none of the STI regions that are adjacent the second transistors are recessed. Additionally, all of the STI regions that are between the first transistors and the second transistors could be recessed.

Following this, a first stress liner is formed over the first transistors and a second stress liner, different than the first stress liner, is formed over the second transistors. Portions of the first stress liner and/or the second stress liner are positioned within the recesses during the forming of the first stress liner and the second stress liner. If all of the STI regions are recessed, then the forming of the first stress liner and the second stress liner includes forming the first stress liner and the second stress liner such that a portion of the first stress liner contacts a portion of the second stress liner within the recesses. If all of the STI regions that are adjacent the first transistors are recessed and none of the STI regions that are adjacent the second transistors are recessed, then portions of the first stress liner are positioned within the recesses during the forming of the first stress liner. Moreover, portions of the second stress liner are not positioned within the recesses during the forming of the second stress liner. The recessing can create the recesses to have a depth larger than a height of the first stress liner and the second stress liner, such that portions of the first stress liner and the second stress liner that are within the recesses can be below a top of the substrate.

Accordingly, the embodiments of the invention disclose structures and methods to enhance complementary metal oxide semiconductor (CMOS) device performance by using optimized STI stress and nitride capping layer. Embodiments herein use STI recess (total recess, recess NFET side, or recess PFET side) combined with a dual-stress nitride capping layer process to achieve NFET and PFET performance enhancement simultaneously, which gives the effects of dual-stress STI and dual CA nitride capping layer. These methods can be integrated with current process flows, which can simultaneously improve both NFET and PFET device performance, and greatly enhance the effect of current dual-stress CA nitride liner.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a diagram illustrating three recessed STI regions;

FIG. 2 is a diagram illustrating recessed STI regions proximate an NFET device;

FIG. 3 is a diagram illustrating recessed STI regions proximate a PFET device;

FIG. 4 is a diagram illustrating a model of a single recessed STI region proximate a transistor;

FIG. 5 is a graph illustrating simulated stress versus distance;

FIG. 6 is a flow diagram illustrating a method to enhance channel stress by using optimized STI stress and nitride capping layer stress; and

FIGS. 7A-7E are diagrams illustrating a method of forming a transistor structure.

### DETAILED DESCRIPTION OF PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

The embodiments of the invention disclose structures and methods to enhance CMOS device performance by using optimized STI stress and nitride capping layer. Embodiments herein use STI recess (total recess, recess NFET side, or recess PFET side) combined with a dual-stress capping layer process to achieve NFET and PFET performance enhancement simultaneously, which gives the effects of dual-stress STI and dual nitride capping layer. These methods can be integrated with current process flows, which can simultaneously improve both NFET and PFET device performance, and greatly enhance the effect of current dual-stress nitride liner.

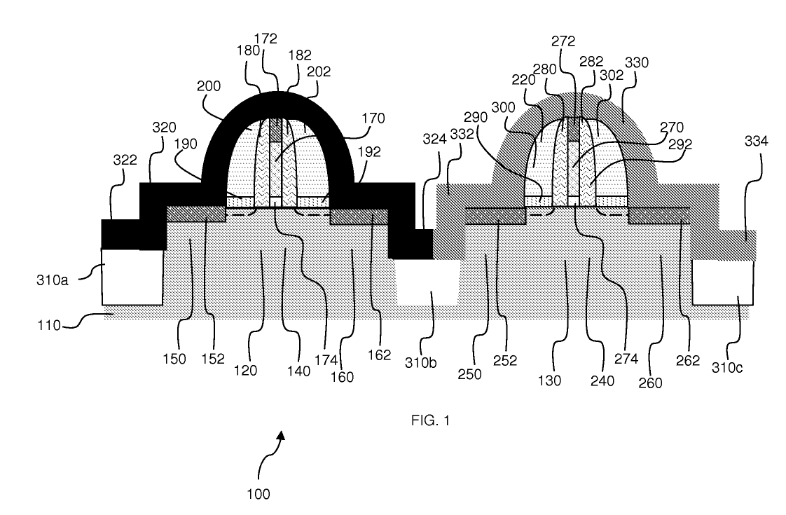

Referring now to the figures, FIG. 1 illustrates a transistor structure 100 wherein all of the STI regions 310 are recessed. The STI regions 310 are recessed before putting in the stress liners 320 and 330. The STI recess can be done before silicide formation or after silicide formation. The recess after silicide formation may have the advantage of lower junction leakage current and better isolation.

More specifically, FIG. 1 illustrates a transistor structure 100 having a substrate 110 (e.g., silicon, silicon on insulator, or other semiconductors), an NFET 120, and a PFET 130. Although the figures illustrate a single NFET adjacent to a single PFET, it is recognized that the transistor structure 100 could include any number and type of transistor devices. More specifically, the NFET 120 includes a channel 140 between a source 150 and a drain 160, and a gate 170 and a gate dielectric 174 over the channel 140. The channel 140 is a high conductivity region connecting the source 150 and the drain 160. The source 150 and the drain 160 are heavily doped regions from which majority carriers flow into the channel 140 through the source 150 and from which majority carriers flow out of the channel 140 through the drain 160. The conductivity of the channel 140 is controlled by the gate 170. Depending on the gate voltage, channel conductivity can be very low (channel “closed”) or very high (channel “open”). By turning the channel 140 “on” and “off” via the gate 170, switching in the NFET 120 is accomplished.

The NFET 120 further includes a source silicide 152 over the source 150 and a drain silicide 162 over the drain 160, wherein the channel 140 is between the source silicide 152 and the drain silicide 162. Top surfaces of the source silicide 152 and the drain silicide 162 are coplanar with a top surface of the substrate 110. Moreover, a gate silicide 172 is on a top surface of the gate 170 and a gate dielectric 174 is below a bottom surface of the gate 170. The gate dielectric 174 is on the top surface of the substrate 110 and over the channel 140.

First spacers 180 and 182 are also provided on the top surface of the substrate 110 and over the channel 140. Specifically, an inner sidewall of the first spacer 180 contacts first sidewalls of the gate dielectric 174, the gate 170, and the gate silicide 172. Similarly, an inner sidewall of the first spacer 182 contacts second sidewalls of the gate dielectric 174, the gate 170, and the gate silicide 172.

Etch stop components 190 and 192 are also provided on the top surface of the substrate 110, wherein the etch stop components 190 and 192 are over the channel 140. Specifically, an inner sidewall of the etch stop component 190 contacts a bottom portion of an outer sidewall of the first spacer 180. Similarly, an inner sidewall of the etch stop component 192 contacts a bottom portion of an outer sidewall of the first spacer 182. Additionally, the NFET 120 includes second spacers 200 and 202 on the etch stop components 190 and 192, respectively. Inner sidewalls of the second spacers 200 and 202 contact the outer sidewalls of the first spacers 180 and 182, respectively.

Similarly, the PFET 130 includes a channel 240 between a source 250 and a drain 260, and a gate 270 over the channel 240. The channel 240 is a high conductivity region connecting the source 250 and the drain 260. The source 250 and the drain 260 are heavily doped regions from which majority carriers flow into the channel 240 through the source 250 and from which majority carriers flow out of the channel 240 through the drain 260. The conductivity of the channel 240 is controlled by the gate 270. Depending on the gate voltage, channel conductivity can be very low (channel “closed”) or very high (channel “open”). By turning the channel 240 “on” and “off” via the gate 270, switching in the NFET 220 is accomplished.

The PFET 130 further includes a source silicide 252 over the source 250 and a drain silicide 262 over the drain 260, wherein in the channel 240 is between the source silicide 252 and the drain silicide 262. Top surfaces of the source silicide 252 and the drain silicide 262 are coplanar with a top surface of the substrate 220. Moreover, a gate silicide 272 is on a top surface of the gate 270 and a gate dielectric 274 is below a bottom surface of the gate 270. The gate dielectric 274 is on the top surface of the substrate 220 and over the channel 240.

First spacers 280 and 282 are also provided on the top surface of the substrate 220 and over the channel 240. Specifically, an inner sidewall of the first spacer 280 contacts first sidewalls of the gate dielectric 274, the gate 270, and the gate silicide 272. Similarly, an inner sidewall of the first spacer 282 contacts second sidewalls of the gate dielectric 274, the gate 270, and the gate silicide 272.

Etch stop components 290 and 292 are also provided on the top surface of the substrate 220, wherein the etch stop components 290 and 292 are over the channel 240. Specifically, an inner sidewall of the etch stop component 290 contacts a bottom portion of an outer sidewall of the first spacer 280. Similarly, an inner sidewall of the etch stop component 292 contacts a bottom portion of an outer sidewall of the first spacer 282. Additionally, the PFET 130 includes second spacers 300 and 302 on the etch stop components 290 and 292, respectively. Inner sidewalls of the second spacers 300 and 302 contact the outer sidewalls of the first spacers 280 and 282, respectively.

In addition, the transistor structure 100 includes STI regions 310 adjacent to the NFET 120 and the PFET 130. For example, as illustrated in FIG. 1, the transistor structure 100 includes STI regions 310a and 310b, wherein the NFET 120 is between the STI regions 310a and 310b, and wherein the STI region 310b is between the NFET 120 and the PFET 130. An STI region 310c is also provided, wherein the PFET 130 is between the STI regions 310b and 310c. In FIG. 1, item 310a can be the STI between the NFET 120 and another NFET (not shown), and item 310c can be the STI between the PFET 130 and another PFET (not shown). Although the figures only illustrate three STI regions, it is recognized that the transistor structure 100 could include any number and arrangement of STI regions.

The STI regions 310a, 310b, and 310c each include recesses such that the top surfaces of the STI regions 310a, 310b, and 310c are below the top surface of the substrate 110. Moreover, the top surfaces of the STI regions 310a, 310b, and 310c can be below the bottom surfaces of the source suicides 152 and 252 and the drain suicides 162 and 262.

The transistor structure 100 further includes a first stress liner 320 over the NFET 120 and a second stress liner 330 over the PFET 130. The first stress liner 320 can be adapted to produce tensile stress; and, the second stress liner 330 can be adapted to produce compressive stress. Specifically, the first stress liner 320 includes a first end 322 and a second end 324, wherein the first end 322 is on the STI region 310a, and wherein the second end 324 is on the STI region 310b. The second stress liner 330 includes a first end 332 and a second end 334, wherein the first end 332 is on the STI region 310b, and wherein the second end 334 is on the STI region 310c. Thus, as illustrated in FIG. 1, the first end 322 and the second end 324 of the first stress liner 320, and the first end 332 and the second end 334 of the second stress liner 330, are below the top surface of the substrate 110. The drawings illustrate that the top surfaces of items 322, 324, 332 and 334 are below the top surface of the substrate 110. Specifically, the top surface of the substrate is the uppermost surface of the substrate 110, in which the etch stop components 190, 192, 290, and 292 are disposed upon. The embodiments herein, however, are not limited to the drawing, and the top surfaces of items 322, 324, 332 and 334 can be above the top surfaces of the substrate 110. The end of the first stress liner 324 and the end of the second stress liner 332 meet in the recessed STI 310b.

Positioning the stress liners 320, 330 within the STI regions 310 results in additional stress within the channel regions 140 that are adjacent the STI regions 310. Depending on the type of stress liner(s) positioned in the STI regions 310, the additional stress imparted on the channel regions 140 could be compressive and/or tensile, and could range in magnitude from 10 MPa to 10 GPa. In other words, positioning the stress liners 320, 330 within the STI regions 310 increases the magnitude of lateral stress that is imparted on the channel regions 140. The increase in lateral stress could be at least 20% higher than the standard stress liner. A compressive stress liner 320/330 within an STI region 310 creates lateral stress that is directed towards the channel region 140 and away from the STI region 310. A tensile stress liner 320/330 within an STI region 310 creates lateral stress that is directed away from the channel region 140 (i.e., stretches the channel region 140) and towards the STI region 310.

Preferably, the transistor structure 100 includes a tensile stress liner 320 and a compressive stress liner 330. The tensile stress liner 320 and the compressive stress liner 330 completely cover the NFET 120, the PFET 130, and the STI regions 310; thus, the STI regions 310a, 310b and 310c are not exposed such that the tensile stress liner 320 and the compressive stress liner 330 also act as a diffusion barrier over the STI region. The STI regions 310a, 310b, and 310c may all produce either tensile or compressive stress on the channels of adjacent FET devices. Thus, the tensile stress liner 320 imparts tensile stress upon the NFET 120; and, the compressive stress liner 330 imparts compressive stress upon the PFET 130. Moreover, the recessing of the STI regions 310a, 310b, and 310c reduces the stress conveyed upon the channel regions of the NFET 120 and the PFET 130 from STI regions and enhances stress from tensile liner 320 on NFET 120 and compressive liner 330 on PFET 130.

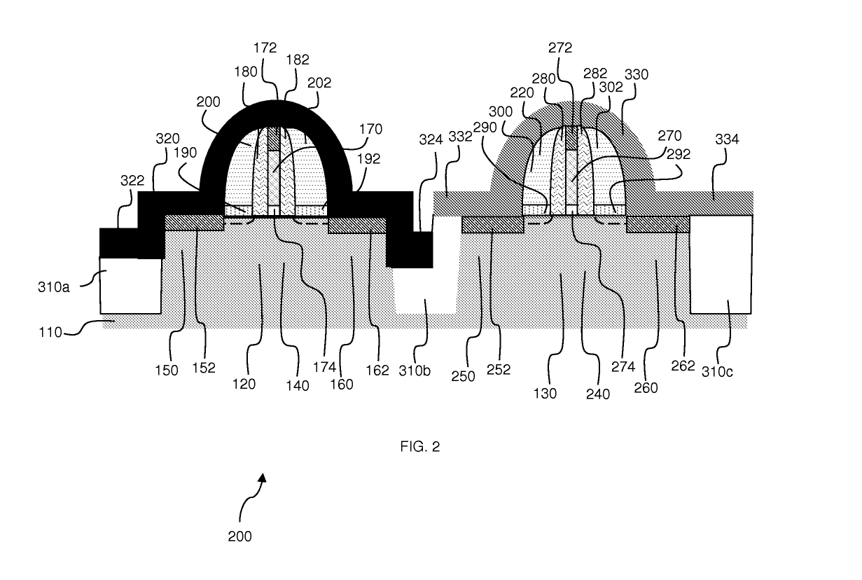

Referring now to FIG. 2, a transistor structure 200 is illustrated having recessed STI regions on the NFET 120 side, and this may be desirable when the STI possesses compressive stress. The STI regions can comprise compressive or tensile stress. Moreover, as described above, compressive stress in the longitudinal direction of the channel can enhance PFET performance but degrade NFET performance. Thus, if the STI regions possess compressive stress, it may be desirable to recess the STI regions proximate the NFET 120 side.

The STI regions are recessed before putting in the stress liners 320 and 330, and the PFET 130 side is protected using masking during the STI recess. If STI is compressive, the negative STI stress on the NFET 120 side will be relaxed due to the recess, and the recess will also cause enhanced stress from tensile capping nitride layer 320 for the NFET 120. The compressive STI stress for the PFET 130 will be maintained for the most part. The STI recess can be done before silicide formation or after silicide formation. The recess after silicide formation may have the advantage of lower junction leakage current and better transistor isolation.

More specifically, a transistor structure 200 is illustrated wherein the STI regions 310a and 310b include recesses, and wherein the STI region 310c does not include a recess. Thus, the STI regions 310a and 310b are below the top surface of the substrate; and, the top surface of the STI region 310c is coplanar with the top surface of the substrate. As described above, the top surface of the substrate is the uppermost surface of the substrate 110, in which the etch stop components 190, 192, 290, and 292 are disposed upon. Moreover, the first end 322 and the second end 324 of the first stress liner 320 are below the top surface of the substrate 110; and, and the first end 332 and the second end 334 of the second stress liner 330 are above the top surface of the substrate 110. Through in the drawing the top surfaces of items 322 and 324 are below the top surface of the substrate 110, the embodiments are not limited to the drawing, and the top surfaces of items 322 and 324 can be above the top surface of the substrate 110 depending on the relative thickness of the nitride capping layer 320 and the recess depth of the STI.

Preferably, the transistor structure 200 includes compressive STI regions 310, a tensile stress liner 320, and a compressive stress liner 330. Thus, the tensile stress liner 320 imparts tensile stress upon the NFET 120; and, the compressive stress liner 330 imparts compressive stress upon the PFET 130. Moreover, recessing the compressive STI regions proximate the NFET 120 reduces the amount of compressive stress imparted upon the channel 140 from STI regions 310a and 310b and enhances tensile stress from tensile stress liner 320 upon the channel 140.

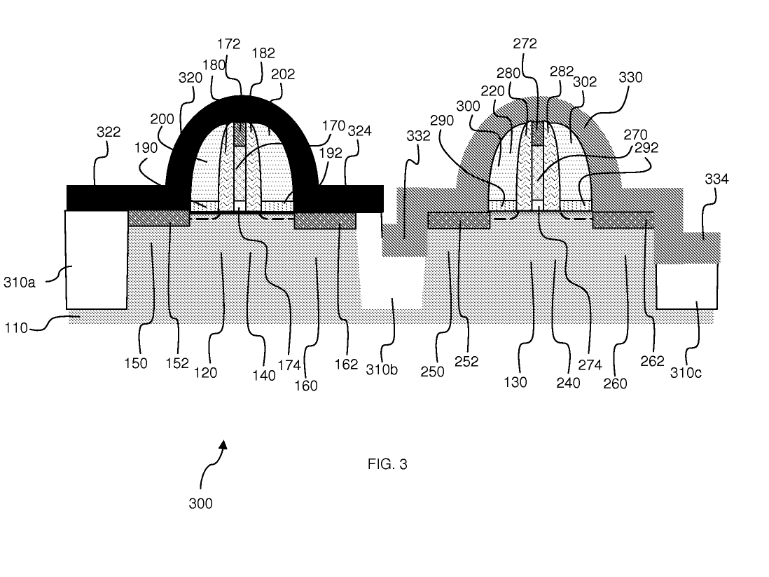

Referring now to FIG. 3, a transistor structure 300 is illustrated having recessed STI regions on the PFET 130 side, which may be desirable when the STI possesses-tensile stress. As described above, the STI regions can comprise compressive or tensile stress. Tensile stress in the longitudinal direction of MOSFET channel regions can enhance NFET performance but degrade PFET performance. Thus, if the STI regions possess tensile stress, it may be desirable to recess the STI regions proximate the PFET 130 side. Furthermore, it may be desirable to recess the STI regions proximate the PFET 130 side and the NFET 120 side in order to completely cover the STI regions. As illustrated in FIG. 1, the STI regions 310a, 310b and 310c are completely covered by the stress liners 320 and 330.

Referring back to FIG. 3, the STI is recessed before putting in the stress liners 320 and 330, and the NFET 120 side is protected using a mask during the STI recess. If the STI is tensile stress, the negative STI stress on the PFET 130 side will be relaxed, and the recess can also cause enhanced stress from compressive capping nitride layer 330 for the PFET 130. The tensile STI stress for the PFET 130 will be maintained for most part. The STI recess can be done before silicide formation or after silicide formation. The recess after silicide formation may have the advantage of lower junction leakage current and better isolation.

More specifically, a transistor structure 300 is illustrated wherein the STI regions 310b and 310c include recesses, and wherein the STI region 310a does not include a recess. Thus, the STI regions 310b and 310c are below the top surface of the substrate; and, the top surface of the STI region 310a is coplanar with the top surface of the substrate. As described above, the top surface of the substrate is the uppermost surface of the substrate 110, in which the etch stop components 190, 192, 290, and 292 are disposed upon. Moreover, the first end 322 and the second end 324 of the first stress liner 320 are above the top surface of the substrate 110; and, and the first end 332 and the second end 334 of the second stress liner 330 are below the top surface of the substrate 110. Through in the drawing the top surfaces of items 332 and 334 are below the top surface of the substrate 110, the embodiments are not limited to the drawing, and the top surfaces of items 332 and 334 can be above the top surface of the substrate 110 depending on the relative thickness of the nitride capping layer 330 and the recess depth of the STI.

Preferably, the transistor structure 300 includes tensile STI regions 310, a tensile stress liner 320, and a compressive stress liner 330. Thus, the tensile stress liner 320 imparts tensile stress upon the NFET 120; and, the compressive stress liner 330 imparts compressive stress upon the PFET 130. Moreover, recessing the tensile STI regions proximate the PFET 130 reduces the amount of tensile stress imparted upon the channel 240 from STI and enhanced the amount of compressive stress from a compressive stress liner 330 upon the channel 240.

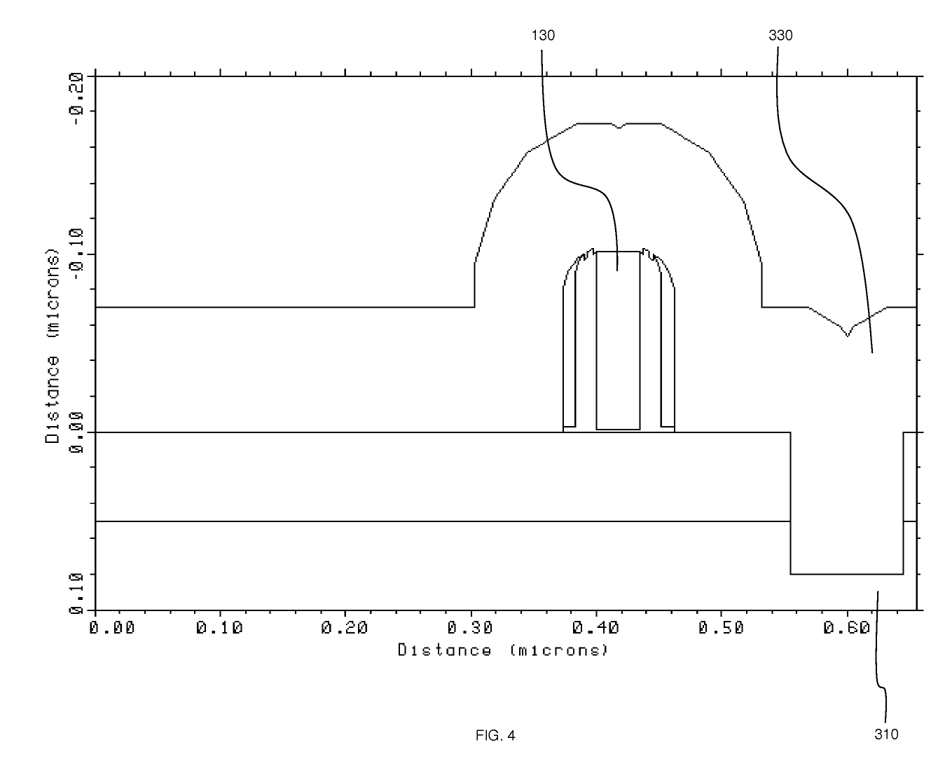

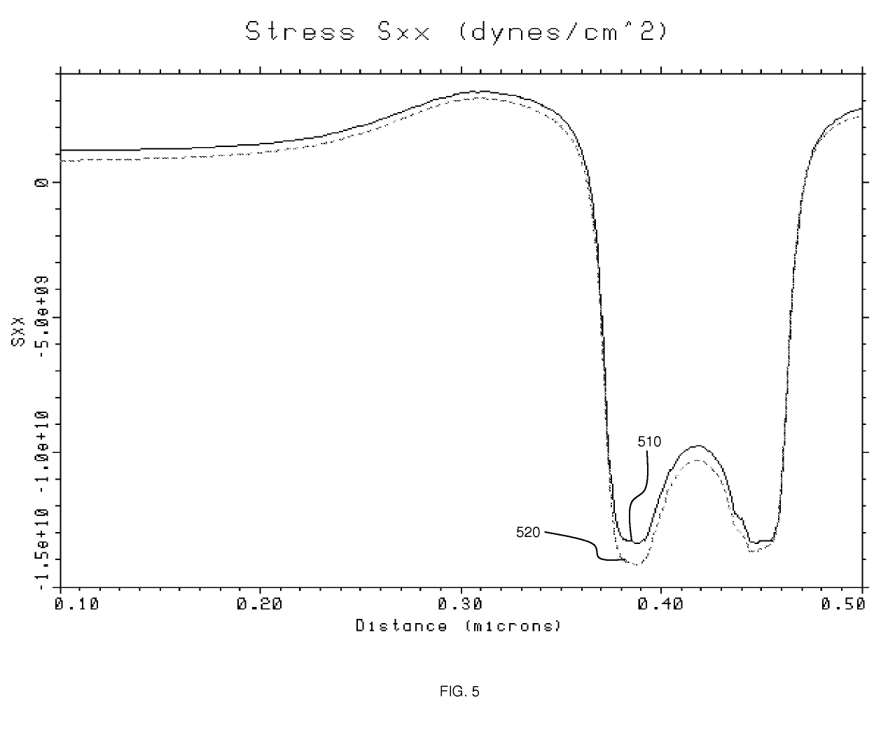

The embodiment illustrated in FIG. 1 is most highly preferred wherein the tensile stress liner 320 and compressive stress liner 330 are both formed in the recessed STI so as to form a diffusion barrier over the STI. Although in the case of an STI material that provides compressive stress on the channel 240 of the adjacent PFET 130, if the STI 310b is recessed so as to reduce the compressive stress on the PFET channel 240 due to the STI, the compressive stress liner 330 includes an portion 332 formed along the sidewall of the recessed STI 310b adjacent the channel 240 of the PFET 130 that compensates for the reduced compressive stress on channel 240 when the STI 310b is recessed. Referring to FIG. 4, a model of a single recessed compressive STI region 310 is shown adjacent a PFET 130, wherein a compressive stress liner 330 covers the PFET 130 and the STI region 310. The graph illustrated in FIG. 5 shows a plot of simulated stress Sxx along the channel direction versus distance. A positive stress Sxx (>0) indicates tensile stress, whereas a negative stress Sxx (<0) indicates compressive stress. The solid line 510 represents the magnitude of stress imposed on the PFET 130 if none of the adjacent STI regions are recessed. The dashed line 520 represents the magnitude of stress imposed on the PFET 130 having the single recessed compressive STI region 310 adjacent thereto (as illustrated in FIG. 4). In this example, the compressive stress on the channel is substantially the same as or increased when the compressive stress liner 330 is formed in a recessed STI, in accordance with the invention, relative to the compressive stress on the channel without the recessed STI.

Accordingly, the embodiments of the invention provide a structure and method to enhance channel stress by using optimized STI stress and nitride capping layer stress. More specifically, a transistor structure is provided comprising a substrate having a first transistor region and a second transistor region, different than the first transistor region. Moreover, first transistors are provided over the first transistor region and second transistors, different in polarity than the first transistors, are provided over the second transistors region. As discussed above, the transistors include a channel between a source and a drain, and a gate over the channel. The first transistor comprises an NFET and the second transistor comprises a PFET. As discussed above, the transistor structure could include any number and type of transistor devices.

The structure further includes STI regions in the substrate adjacent sides of the first transistors and the second transistors, wherein the STI regions comprise stress producing regions. As discussed above, the transistor structure could include any number and arrangement of STI regions. Recesses are within at least two of the STI regions, such that tops of the STI regions that are recessed are below a top of the substrate. As discussed above, the top surfaces of the STI regions can be below bottom surfaces of source and drain suicides.

Additionally, a first stress liner is over the first transistors and a second stress liner, different than the first stress liner, is over the second transistors. As discussed above, the first stress liner can be adapted to produce tensile stress; and, the second stress liner can be adapted to produce compressive stress. Portions of the first stress liner and/or the second stress liner are positioned within the recesses. If all of the STI regions are recessed, then a portion of the first stress liner contacts a portion of the second stress liner within the recesses. If all of the STI regions that are adjacent the first transistors are recessed and none of the STI regions that are adjacent the second transistors are recessed, then portions of the first stress liner are positioned within the recesses and portions of the second stress liner are not positioned within the recesses. As discussed above, the first stress liner can include a first end and a second end, wherein the first and second ends are on STI regions; and, the second stress liner can include a first end and a second end, wherein the first and second ends are on STI regions. The recesses have a depth larger than a height of the first stress liner or the second stress liner, such that portions of the first stress liner or the second stress liner that are within the recesses are below a top of the substrate. Or the recesses have a depth smaller than a height of the first stress liner or the second stress liner, such that portions of the first stress liner or the second stress liner that are within the recesses are above a top of the substrate.

Furthermore, all of the STI regions could be recessed. Thus, as illustrated in FIG. 1, the first and second ends of the first stress liner, and the first and second ends of the second stress liner, are positioned in the recessed STI region. Alternatively, all of the STI regions that are adjacent the first transistor could be recessed; wherein none of the STI regions that are adjacent the second transistors are recessed. The first and second ends of the first stress liner are in the recessed STI region, while the first and second ends of the second stress liner are on the un-recessed STI region. The first and second ends of the second stress liner are above the top surface of the substrate. Or all of the STI regions that are adjacent the second transistor could be recessed; wherein none of the STI regions that are adjacent the first transistors are recessed. The first and second ends of the second stress liner are in the recessed STI region, while the first and second ends of the first stress liner are on the un-recessed STI region. The first and second ends of the first stress liner are above the top surface of the substrate.

The embodiments of the invention also provide a method of forming a transistor structure, wherein the method begins by forming first transistors over a first transistor region of a substrate and forming second transistors over a second transistor region of the substrate. As discussed above, the transistors can include first and second spacers and etch stop components. The first transistors comprise NFETs and the second transistors comprise PFETs. As discussed above, the transistor structure could include any number and type of transistor devices.

Next, STI regions are formed in the substrate adjacent sides of the first transistors and the second transistors such that the STI regions comprise stress producing regions. As discussed above, the transistor structure could include any number and arrangement of STI regions. The STI regions are then recessed, such that all of the STI regions can be recessed.

Thus, as discussed above, the top surfaces of the STI regions are below the top surface of the substrate. Alternatively, all of the STI regions that are adjacent the first transistors can be recessed; wherein none of the STI regions that are adjacent the second transistors are recessed. Additionally, all of the STI regions that are adjacent the second transistors can be recessed; wherein none of the STI regions that are adjacent the first transistors are recessed. As discussed above, the STI recess can be done before silicide formation or after silicide formation. The recess after silicide formation may have the advantage of lower junction leakage current and better isolation.

Following this, a first stress liner is formed over the first transistors and a second stress liner, different than the first stress liner, is formed over the second transistors. As discussed above, the first stress liner can be adapted to produce tensile stress; and, the second stress liner can be adapted to produce compressive stress. Portions of the first stress liner and/or the second stress liner are positioned within the recesses during the forming of the first stress liner and the second stress liner. If all of the STI regions are recessed, then the forming of the first stress liner and the second stress liner includes forming the first stress liner and the second stress liner such that a portion of the first stress liner contacts a portion of the second stress liner within the recesses. If all of the STI regions that are adjacent the first transistors are recessed and none of the STI regions that are adjacent the second transistors are recessed, then portions of the first stress liner are positioned within the recesses during the forming of the first stress liner. Moreover, portions of the second stress liner are not positioned within the recesses during the forming of the second stress liner. As discussed above, the first stress liner can include a first end and a second end, wherein the first and second ends are on STI regions; and, the second stress liner can include a first end and a second end, wherein the first and second ends are on STI regions.

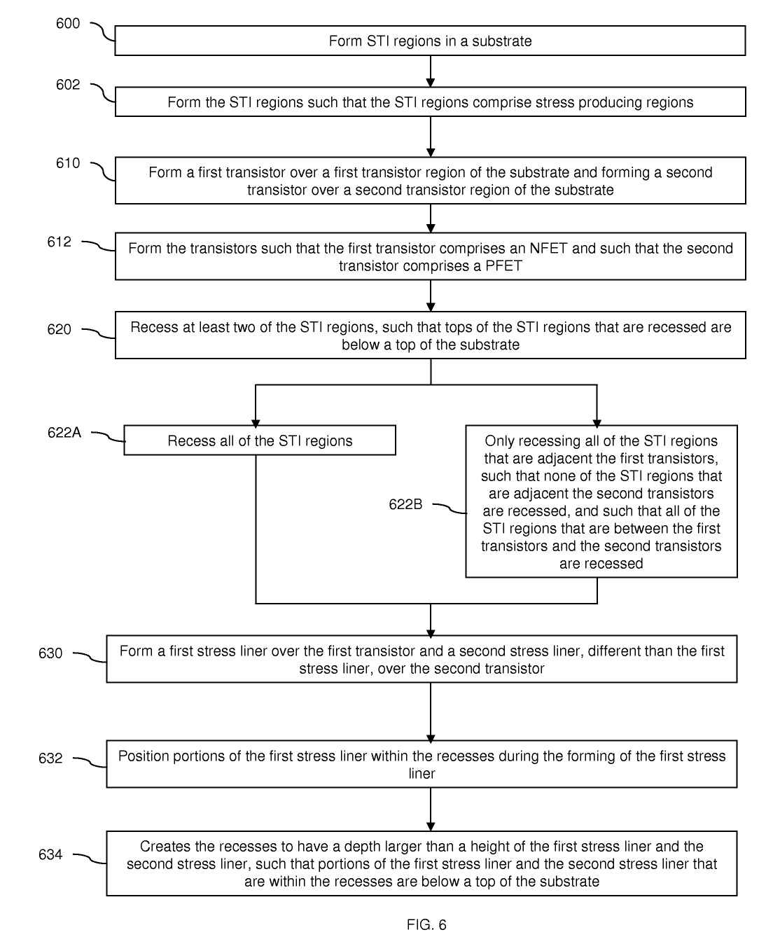

FIG. 6 is a flow diagram illustrating a method to enhance channel stress by using optimized STI stress and nitride capping layer stress. The method begins in item 600 by forming STI regions in a substrate. This involves, in item 602, forming the STI regions such that the STI regions comprise stress producing regions. As discussed above, the transistor structure could include any number and arrangement of STI regions.

Next, in item 610, the method forms a first transistor over a first transistor region of the substrate and a second transistor over a second transistor region of the substrate. The STI regions are adjacent sides of the first transistor and the second transistor. As discussed above, the transistors include a channel between a source and a drain, and a gate over the channel. In item 612, the transistors are formed such that the first transistor comprises an NFET and such that the second transistor comprises a PFET. As discussed above, the transistor structure could include any number and type of transistor devices.

Following this, in item 620, at least two of the STI regions are recessed, such that tops of the STI regions that are recessed are below a top of the substrate. In item 622A, the method could include recessing all of the STI regions. Thus, as discussed above, the top surfaces of the STI regions can be below the bottom surfaces of the source and drain silicides. Alternatively, in item 622B, the method could include only recessing all of the STI regions that are adjacent the first transistors, such that none of the STI regions that are adjacent the second transistors are recessed and such that all of the STI regions that are between the first transistors and the second transistors are recessed. As discussed above, the STI recess can be done before suicide formation or after silicide formation. The recess after silicide formation may have the advantage of lower junction leakage current and better isolation.

Subsequently, in item 630, the method forms a first stress liner over the first transistor and a second stress liner, different than the first stress liner, over the second transistor. This involves, in item 632, positioning portions of the first stress liner within the recesses during the forming of the first stress liner. As discussed above, the first stress liner can include a first end and a second end, wherein the first and second ends are on STI regions; and, the second stress liner can include a first end and a second end, wherein the first and second ends are on STI regions. As discussed above, the first stress liner can be adapted to produce tensile stress; and, the second stress liner can be adapted to produce compressive stress.

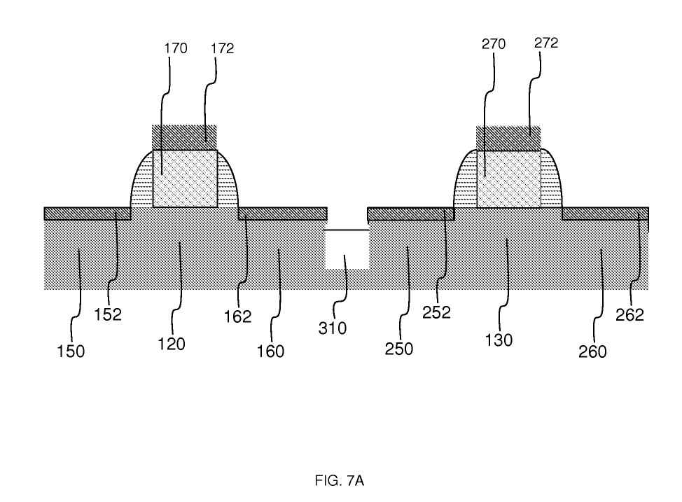

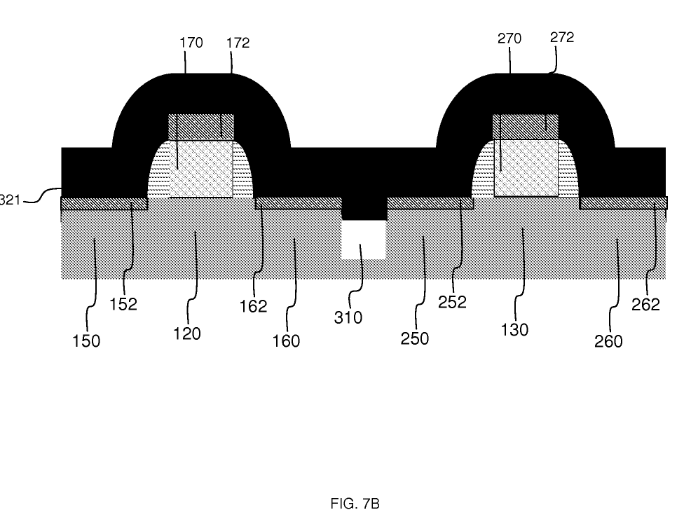

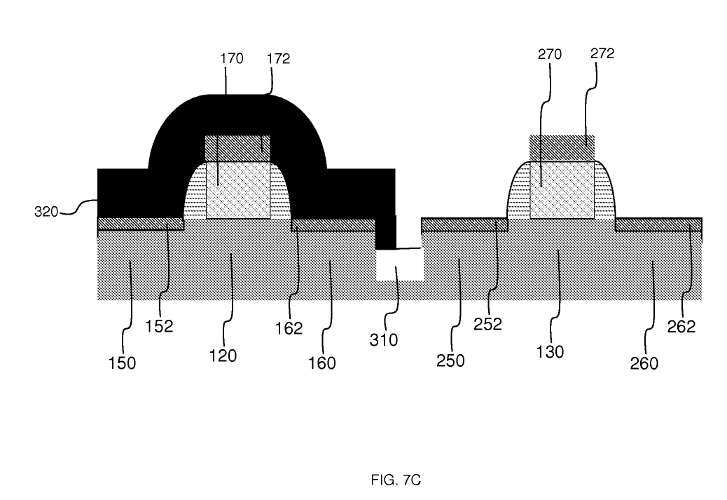

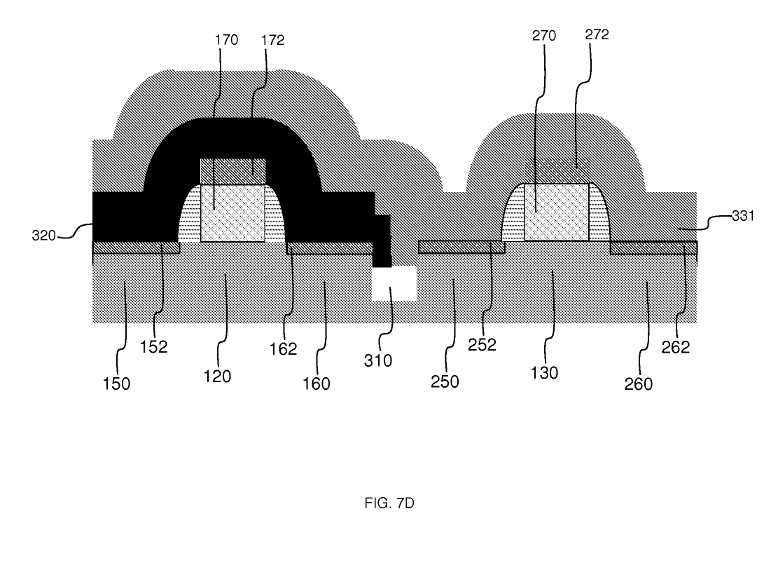

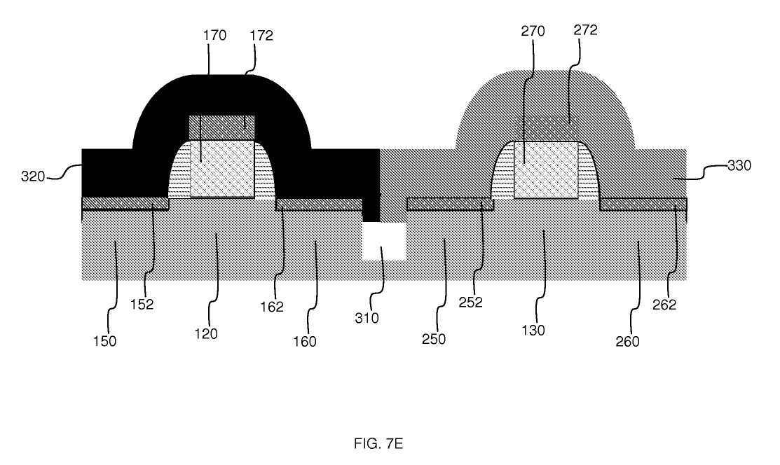

FIGS. 7A-5E illustrate a method of forming the transistor structure 100. Many of the details of forming silicides, stress layers, recessing STI regions, masking, etching, etc., are well-known and are not discussed herein in detail so as to focus the reader on the salient portions of the invention. Instead, reference is made to U.S. Patent Publication 20060270136 to Doris et al. for the description of such details and the same are fully incorporated herein by reference.

Referring to FIG. 7A, the method begins with silicide formation and STI recessing processes. More specifically, the gate silicide 172 is formed on the gate 170, the source silicide 152 is formed over the source 150, and the drain silicide 162 is formed over the drain 160. Similarly, the method forms the gate silicide 272 on the gate 270, the source silicide 252 over the source 250, and the drain silicide 262 over the drain 260. Furthermore, the method recesses the STI region 310 between the NFET 120 and the PFET 130. This can be performed, for example, by selective dry plasma etching or by wet etching. Recessing the STI region 50-500A enhances channel stress. The STI region 310 is preferably recessed after silicide formation due to leakage concerns; however, it is recognized that silicide formation could be performed first.

Next, as illustrated in FIG. 7B, a first stress layer 321 is formed on the STI region 310, the NFET 120, and the PFET 130. Following this, a mask (not shown) is positioned over the NFET 120 and over a portion of the STI region 310 that is adjacent the NFET 120. An exposed portion of the first stress layer 321 that is over the PFET 130 is etched; and, the mask is removed. Thus, as illustrated in FIG. 7C, the first stress liner 320 is left (formed).

Subsequently, as illustrated in FIG. 7D, a second stress layer 331 is formed on the first stress liner 320, an uncovered portion of the STI region 310 that is adjacent to the PFET 130, and the PFET 130. The method then positions a mask (not shown) over the PFET 130 and the portion of the STI region 310 that is adjacent the PFET 130. An exposed portion of the second stress layer 331 that is over the NFET 120 is etched; and, the mask is removed. Thus, as illustrated in FIG. 7E, the second stress liner 330 is left (formed).

Accordingly, the embodiments of the invention disclose structures and methods to enhance CMOS device performance by using optimized STI stress and nitride capping layer. Embodiments herein use STI recess (total recess, recess NFET side, or recess PFET side) combined with a dual-stress CA capping layer process to achieve NFET and PFET performance enhancement simultaneously, which gives the effects of dual-stress STI and dual CA nitride capping layer. These methods can be integrated with current process flows, which can simultaneously improve both NFET and PFET device performance, and greatly enhance the effect of current dual-stress CA nitride liner.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A transistor structure comprising:
a substrate having a first transistor region and a second transistor region, different than said first transistor region;
a first transistor over said first transistor region and a second transistor, different than said first transistor, over said second transistor region;
shallow trench isolation regions in said substrate adjacent sides of said first transistor and said second transistor;
recesses within at least two of said shallow trench isolation regions, such that tops of said shallow trench isolation regions that are recessed are below a top of said substrate; and
a first stress liner over said first transistor and a second stress liner, different than said first stress liner, over said second transistor.

2. The transistor structure according to claim 1, wherein all of said shallow trench isolation regions are recessed.

3. The transistor structure according to claim 1, wherein said first transistor comprises a N-type field effect transistor (NFET) and said second transistor comprises a P-type field effect transistor (PFET).

4. The transistor structure according to claim 1, wherein portions of at least one of said first stress liner and said second stress liner are positioned within said recesses.

5. The transistor structure according to claim 1, wherein a portion of said first stress liner contacts a portion of said second stress liner within said recesses.

6. A transistor structure comprising:
a substrate having a first transistor region and a second transistor region, different than said first transistor region;
first transistors over said first transistor region and second transistors, different than said first transistors, over said second transistors region;
shallow trench isolation regions in said substrate adjacent sides of said first transistors and said second transistors;
recesses within at least two of said shallow trench isolation regions, such that tops of said shallow trench isolation regions that are recessed are below a top of said substrate;
a first stress liner over said first transistors and a second stress liner, different than said first stress liner, over said second transistors,
wherein all of said shallow trench isolation regions that are adjacent said first transistor are recessed,
wherein none of said shallow trench isolation regions that are adjacent said second transistors are recessed, and
wherein all of said shallow trench isolation regions that are between said first transistors and said second transistors are recessed.

7. The transistor structure according to claim 6, wherein said shallow trench isolation regions comprise stress producing regions.

8. The transistor structure according to claim 6, wherein said first transistor comprises a N-type field effect transistor (NFET) and said second transistor comprises a P-type field effect transistor (PFET).

9. The transistor structure according to claim 6, wherein portions of said first stress liner are positioned within said recesses.

10. The transistor structure according to claim 6, wherein portions of said second stress liner are not positioned within said recesses.

11. A method of forming a transistor structure, said method comprising:
forming a first transistor over a first transistor region of a substrate and forming a second transistor over a second transistor region of said substrate;
forming shallow trench isolation regions in said substrate adjacent sides of said first transistor and said second transistor;
recessing at least two of said shallow trench isolation regions, such that tops of said shallow trench isolation regions that are recessed are below a top of said substrate; and
forming a first stress liner over said first transistor and a second stress liner, different than said first stress liner, over said second transistor.

12. The method according to claim 11, wherein said recessing recesses all of said shallow trench isolation regions.

13. The method according to claim 11, wherein said first transistor comprises a N-type field effect transistor (NFET) and said second transistor comprises a P-type field effect transistor (PFET).

14. The method according to claim 11, wherein portions of at least one of said first stress liner and said second stress liner are positioned within said recesses during said forming of said first stress liner and said second stress liner.

15. The method according to claim 11, wherein said forming of said first stress liner and said second stress liner comprises forming said first stress liner and said second stress liner such that a portion of said first stress liner contacts a portion of said second stress liner within said recesses.

16. A method of forming a transistor structure, said method comprising:
forming first transistors over a first transistor region of a substrate and forming second transistors over a second transistor region of said substrate;
forming shallow trench isolation regions in said substrate adjacent sides of said first transistors and said second transistors;
recessing said shallow trench isolation regions, such that all of said shallow trench isolation regions that are adjacent said first transistors are recessed, none of said shallow trench isolation regions that are adjacent said second transistors are recessed, and all of said shallow trench isolation regions that are between said first transistors and said second transistors are recessed; and
forming a first stress liner over said first transistors and a second stress liner, different than said first stress liner, over said second transistors.

17. The method according to claim 16, wherein said forming of said shallow trench isolation regions comprises forming said shallow trench isolation regions such that said shallow trench isolation regions comprise stress producing regions.

18. The method according to claim 16, wherein said first transistors comprises a N-type field effect transistor (NFET) and said second transistors comprises a P-type field effect transistor (PFET).

19. The method according to claim 16, wherein portions of said first stress liner are positioned within said recesses during said forming of said first stress liner.

20. The method according to claim 16, wherein portions of said second stress liner are not positioned within said recesses during said forming of said second stress liner.
